(19) United States
(12) Patent Application Publication
(10) Pub. No.: US 2010/0090270 A1
(43) Pub. Date: Apr. 15, 2010

(54) TRENCH MOSFET WITH SHORT CHANNEL FORMED BY PN DOUBLE EPITAXIAL LAYERS

(75) Inventor: Fu-Yuan Hsieh, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/249,453

(22) Filed: Oct. 10, 2008

(51) Int. Cl. H01L 47/00

(52) U.S. Cl. 257/328; 257/E47.001

(57) ABSTRACT

A power MOS device includes double epitaxial (P/N) structure is disclosed for reduction of channel length and better avalanche capability. In some embodiments, the power MOS device further includes an arsenic Ion implantation area underneath each rounded trench bottom to further enhance breakdown voltage and further reduce Rds, and the concentration of said arsenic doped area is higher than that of N-type epitaxial layer. As the gate contact trench could be easily etched over to penetrate the gate oxide, which will lead to a shortage of tungsten plug filled in gate contact trench to epitaixial layer, a terrace poly gate is designed in a preferred embodiment of present invention. By using this method, the gate contact trench is lifted to avoid the shortage problem.

### FIELD OF THE INVENTION

This invention relates generally to the cell configuration and fabrication process of trench MOSFET devices. More particularly, this invention relates to a novel and improved cell structure and improved process of fabricating a trench MOSFET of short channel with better avalanche capability.

### BACKGROUND

Conventional technology of forming a body region of a MOSFET is by the method of implantation and diffusion using a dopant of opposite polarity to substrate, which is encountering a technical difficulty because of a trade-off between channel resistance and avalanche capability. The channel resistance is one of the most important measures of device performance, as well as the avalanche capability, including the avalanche sustaining current and where the avalanche breakdown occurs. Low channel resistance can be achieved by applying a short channel, which, however, may result in the decreasing of breakdown voltage due to punch-through (the body dose between source and epitaxial layer is not enough during reverse bias between drain and source) causing avalanche capability degradation. Therefore, several methods were represented in prior arts reducing the trade-off to achieve the highest performance.

In U.S. Pat. No. 6,084,264, a trench MOSFET was disclosed to reduce the on-resistance and increase avalanche capability, as shown in FIG. 1. A trench MOSFET is grown on a heavily N doped substrate 32, onto which a P-type epitaxial layer 34 is implemented. Particularly, an N drain region 33 is implanted through the trench bottom 35 into the P-type epitaxial layer, said trench 35 is filled with polysillion 37 with a layer of oxide 39 along the sidewall. Source regions 36 of N-doped is formed adjacent the sidewall of trench 35, and P+ contact areas 38, which is applied to contact the metal layer 31 with P-body region 34. In FIG. 2, another structure in U.S. Pat. No. 6,784,505 was illustrated. The structure includes: a P-type epitaxial layer 72 overlying the N+ doped substrate 32, trenches 80 penetrating into said epitaxial layer and source region 37 formed adjacent each wall of said trench near the front surface of said epitaxial layer, and P+ doped body region 75 implanted adjacent the source region. The drain regions 27 are also implanted through the bottom of trenches 80, but different to the former prior art, the drain regions of this structure are merged together to further reduce the channel resistance by increasing cell density. Both structures mentioned above are able to obtain a shorter channel length and a lower channel resistance with better avalanche capability. This is because that doping profile is uniform along channel region (the P-expitaxial layer has uniform doping concentration) which yields higher total net charge in the P-body underneath source for a given threshold. In comparison with traditional technique using ion implantation and diffusion, the P-body doping profile is Gaussian distribution which has less total net charge than the prior arts. However, there is still a big problem with these structures in the prior arts with drain regions implanted around the bottom of trenches in P-type epitaxial layer as described below.

The implanted drain region underneath trench bottom, as shown in FIG. 1 and FIG. 2, requires lots of furnace diffusion recipes for various thickness of epitaxial layer sustaining various avalanche voltages. It means that in the processing step, thicker epitaxial layer requires longer diffusion cycle in order to allow the implanted drain region diffuses though the epitaxial layer, while thinner epitaxial layer may only require shorter diffusion time. This is usual not allowed for mass production since there are many different products with different epitaxial layers, requiring lots of furnace for the implanted drain diffusion and resulting in a cost of time and the furnace resource.

Accordingly, it would be desirable to provide a trench MOSFET element with shorter channel for channel resistance reduction, and with better avalanche capability, and particularly, with lower loss for cost saving, and for mass production.

### SUMMARY OF THE INVENTION

It is therefore an object of the present invention to provide new and improved power MOS element and manufacture process having the ability of reducing the channel resistance and improving the performance of avalanche capability.

One aspect of the present invention is that, P/N double epitaxial layer structure is formed, which means that the P-body region is formed by P-type epitaxial layer and N drift region formed by N-type epitaxial layer. Besides the same function as the N drain of prior arts, the P/N double epitaxial layer has another advantage, which does not need ion implantation and subsequent diffusion for various avalanche voltage and therefore achieving the cost saving.

Another aspect of the present invention is that, the bottom of the trench is etched to be rounded instead of rectangular, by using of this method, the density of electric field around the bottom of the trench is lower, therefore enhanced the breakdown voltage.

Another aspect of the present invention is that, in some embodiments, there is an Arsenic Ion implantation area around the trench bottom, and the concentration of this area is heavier than that of the N-epitaxial layer, which will further reduce channel length and on-resistance.

Another aspect of the present invention is that, in some prior arts, there is a problem that the tungsten plug in trench gate may be shorted to epitaxial layer by over-etching, and this can be prevented by forming a terrace poly to provide adequate poly for dry poly etch as will be discussed below.

Briefly, in a preferred embodiment, the present invention disclosed a power MOS element comprising: an N+ doped substrate with a layer of Ti/Ni/Ag on the rear side serving as the drain metal; a drift region with a doping of a first doping type; a P-body region of a second doping type; a source region of heavily N type doped formed at the top surface of the substrate; a plurality of gate trenches with rounded bottom is etched through said source region and said P-body region, and extended into said drift region. And what should be noticed is that, the trench gates for gate metal contact are designed to be wider than those in active area. To fill the trench, the trench-filling material could be doped poly, or combination of doped poly and non-doped poly, and if only doped poly is used, it is necessary to form a silicide on top poly or inside of the doped poly as alternative for lowing gate resistance. Connecting trenches are etched through an insulating layer, said source region and said P-body region with a layer of Ti/TiN alongside the wall as source contact trench, body contact and gate contact trench, respectively, and then filled with tungsten as plugs. Underneath the source contact trench and body contact trench, an area of P+ doped is form by Ion implantation to further reduce contact resistance between the P-body and the Ti/TiN layer. Said source region and said P-body region are connected to source metal via said source-body contact trench, and said trench gate is connected to gate metal via said gate contact trench. Additional, the power device further includes trench floating rings as termination to sustain breakdown voltage.

Briefly, in another preferred embodiment, the present invention disclosed a power MOS element with an terrace poly for gate metal contact comprising: an N+ doped substrate on which formed a drift region with a doping of a first doping type; a P-body region of a second doping type; a source region of heavily N doped formed at the top surface of the substrate; a plurality of gate trenches with rounded bottom is etched through said source region and said P-body region, and extended into said drift region. And what should be noticed is that, the trench gates for gate metal contact are designed to be wider that those in active area. To fill the trench, the trench-filling material could be doped poly, or combination of doped poly and non-doped poly as alternative for lowing gate resistance. In accordance with the present invention of this embodiment, it is necessary to apply additional mask for the terrace gate formation, and the width of poly remained for gate metal contact is not greater that trench gate width to further improve gate oxide integrity, because of no overlap between terrace gate and top trench corner due to thinner gate oxide around trench corner. Underneath the source-body contact trench, an area of P+ doped is form by Ion implantation to make ohmic contact between the body and source metal. Said source region and said P-body region are connected to source metal via the source-body contact trench, said trench gate is connected to gate metal via a gate contact trench, and all said contact trench are filled with tungsten plugs over a layer of Ti/TiN alongside the trench wall.

Briefly, in another preferred embodiment, the structure disclosed is the same as structure mentioned in the first embodiment expect that, around the bottom of each trench, an n* region doped with a concentration heavier than that of epitaxial layer is formed to further reduce Rds.

Briefly, in another preferred embodiment, the structure disclosed is the same as structure mentioned in the second embodiment expect that, around the bottom of each trench, an n* region doped with a concentration heavier than that of epitaxial layer is formed to further reduce Rds.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a power MOS element of prior art;

FIG. 2 is a side cross-sectional view of a power MOS element of another prior art;

FIG. 3 is cross-section of a power MOS element of the first embodiment for the present invention;

FIG. 4 is a cross-section of a power MOS element of another embodiment for the present invention;

FIG. 5 is a cross-section of a power MOS element of another embodiment for the present invention;

FIG. 6 is a cross-section of a power MOS element of another embodiment for the present invention; and

FIG. 7A to 7E are a serial of side cross sectional views for showing the processing steps for fabricating a power MOS element as shown in FIG. 5.

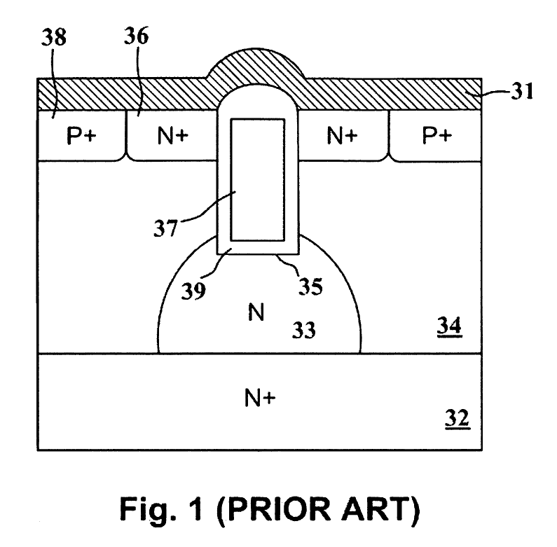

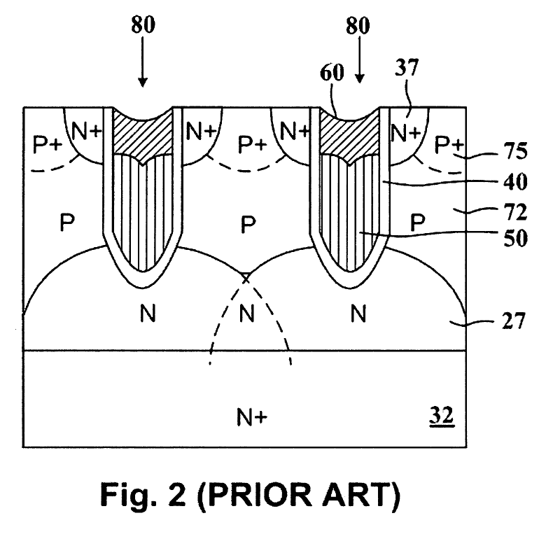

### DETAILED DESCRIPTION OF THE EMBODIMENTS

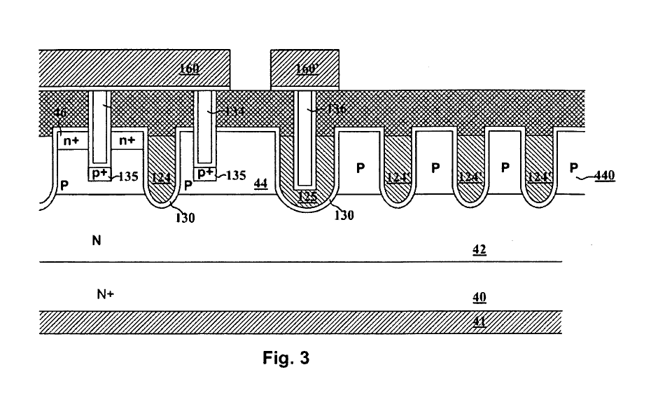

Refer to FIG. 3 for a preferred embodiment of this invention, a MOS element is formed on a substrate 40, onto which formed a first semiconductor type epitaxial layer 42 and a second semiconductor type epitaxial layer 440 with uniform doping concentration across the first semiconductor type epitaxial layer 42. The MOS element further includes a plurality of trenches filled up polysilicon to form a plurality of narrow trench gates 124, a plurality of terminated trenches 124′, and at least a wide trench gate 125 respectively, and each trench is covered with a gate insulation layer 130 on the inner surface thereof. The narrow trench gates 124 and the wide trench gate 125 are served as the gates of the MOS element, and the terminated trenches 124′ are served as floating trench rings as termination. The wide trench gate 125 for gate metal contact is wider than the narrow trench gates 124. It should be noticed that, the bottom of each trench, as shown in FIG. 3, is designed to be rounded to form shallow trench for further reducing gate charge and improving gate oxide integrity. The second semiconductor type epitaxial layer 440 has a plurality of body regions 44 which are formed between each pair of the narrow trenched gates 124 or between the wide trench gate 125 and the narrow trenched gate 124 near the wide trench gate 125. The MOS element further includes a plurality of source regions 46 which are formed by a first semiconductor type doping on the top of the second semiconductor type epitaxial layer 440. The MOS element further includes a insulating layer 150 covered on the source regions 46, and a source metal 160 and a gate metal 160′ which are covered on the insulating layer 150 and isolated to each other. The MOS element further includes a plurality of source contact plugs 134 and at least a gate contact plug 136 corresponding to the wide trench gate 125. The each source contact plug 134 is extended from the source metal 160 and through the insulating layer 150 to contact the corresponding source regions 46 and the corresponding body region 44. At the bottom of each source contact plug 134, a contact implantation part 135 is carried out by a second semiconductor type doping, which will help to form a low-resistance contact between contact plug 134 and the body region 44. The each source contact plug 134 acts as a connecting metal to connect the source metal 160 to the corresponding source region 46 and the corresponding body region 44. The gate contact plug 136 is extended from the gate metal 160′ and through the insulating layer 150 to contact the corresponding wide trench gate 125. The each source contact plug 134 acts as a connecting metal to connect the gate metal 160′ to the corresponding wide trench gate 125. The each said metal plug can be made of tungsten.

In the said embodiment above, the first semiconductor can be the N-type semiconductor while the second semiconductor can be the P-type semiconductor while. Besides, the said substrate 40 and the said source regions 46 have higher N-type doping concentration than the first semiconductor type epitaxial layer 42. The each said contact implantation part 135 has higher P-type doping concentration than the body region 44. The each body region 44 is doped with a uniform dopant of second semiconductor type along channel region, e.g., P-type dopant, extends between the trench gates. To target a given threshold voltage and a short channel length, the uniform distribution of the body region 44 has more tolerance over punch through issue than the conventionally diffused type body of which doping concentration has non-uniform Gaussian distribution.

The polysilicon in the said narrow trench gates 124 and the polysilicon in the wide trench gate 125 are connected to form a gate region like a trench gate region in ordinary trench MOS so that the narrow trench gates 124 are electrically connected to the gate metal 160′ through the wide trench gate 125 and the gate contact plug 136.

In the said MOS element, the substrate 40 can be coated with a back metal 41 on rear side as drain, and the back metal 41 can be made of Ti/Ni/Ag.

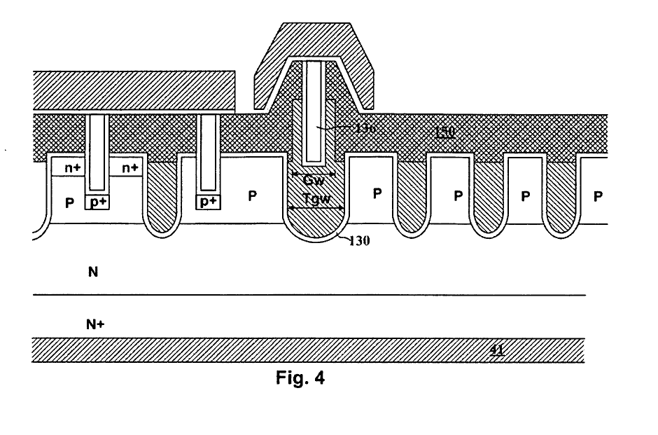

For the purpose of avoiding the connecting trench penetrating through oxide layer and resulting in shortage of tungsten plug to epitaxial layer when the trench depth becomes shallower, a terrace poly gate is designed, as shown in FIG. 4. Additional poly mask is needed here to form terrace poly gate above wide trench, which can effectively lift the gate contact trench to a higher place to avoid the tungsten plug penetrating through oxide layer. For a better embodiment, the wide trench gate 125 is extended into the insulating layer 150 covered on the top thereof so the wide trench gate 125 has polysilicon which is higher than the narrow trenched gates 124. Since the gate contact plug 136 is extended the same depth as the source contact plug 134, the source contact plug 134 penetrates through the wide trench gate 125 is avoided.

Refer to FIG. 4 again, Tgw represents the width of the wide trench gate 125 for gate contact while Gw indicates the gate width above the wide trench gate 125, the portion of poly remained for gate metal contact. The Gw is designed to be smaller than Tgw to improve gate oxide integrity, as no overlap between terrace gate and top trench corner due to thinner gate oxide around trench corner. In FIG. 8B, before the deposition of Al alloys, an additional mask is needed to form a terrace poly gate. With this method, the contact trench for gate contact is lifted to prevent the shortage of tungsten plug to epitaxial layer.

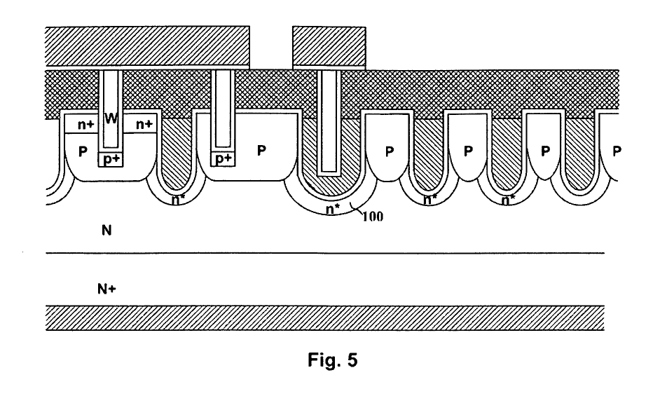

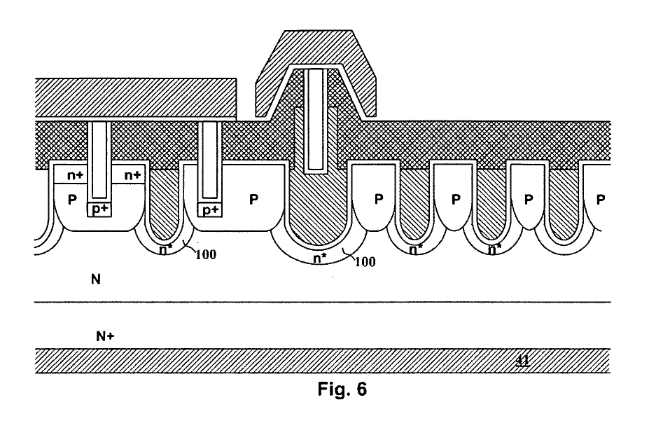

Refer to FIG. 5 for another embodiment of this invention and compare the FIG. 3, in order to further reduce the channel length, an underneath doped area 100 which is heavily doped with Arsenic added underneath each bottom of the narrow trenched gates 124 and the wide trench gate 125. Refer to FIG. 6 for another embodiment of this invention and compare the FIG. 4, similarly, the same heavily Arsenic doped area is also added to the structure in FIG. 4 so the underneath doped area 100 is also formed at the each bottom of the narrow trenched gates 124 and the wide trench gate 125 shown in FIG. 6.

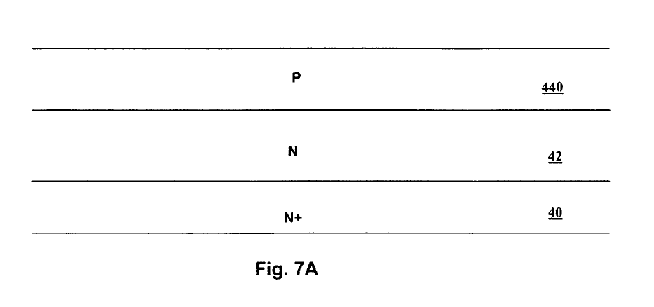

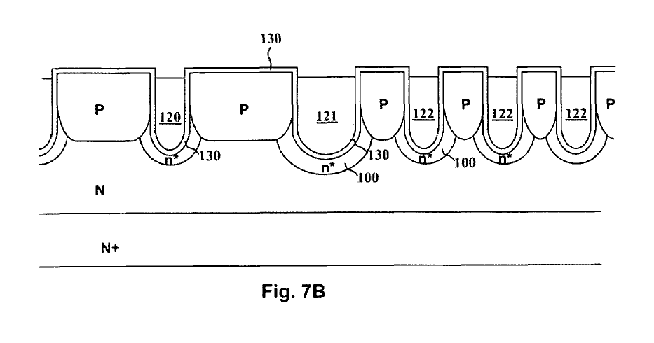

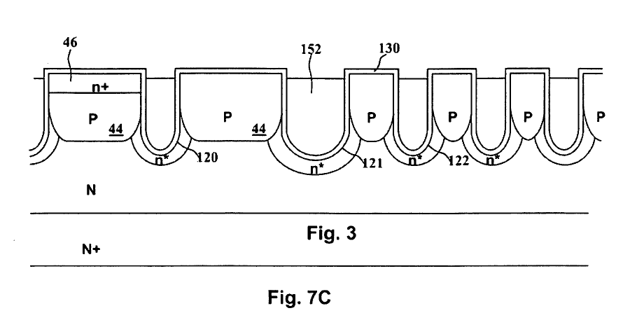

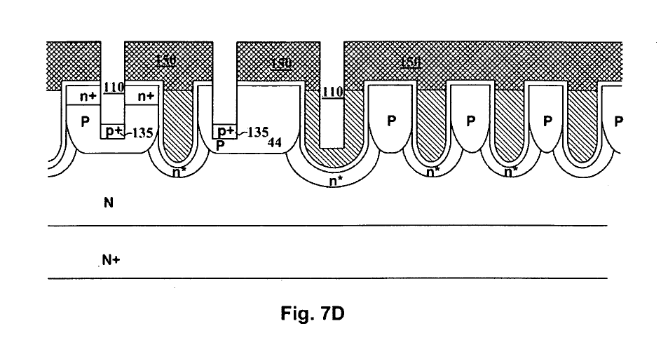

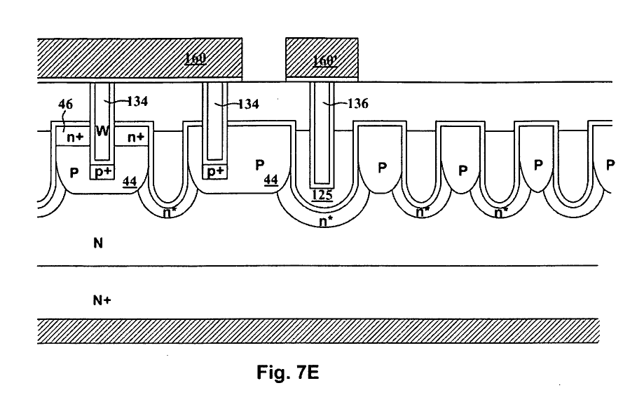

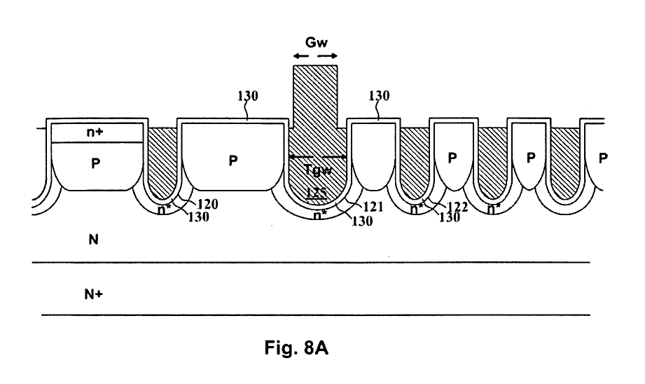

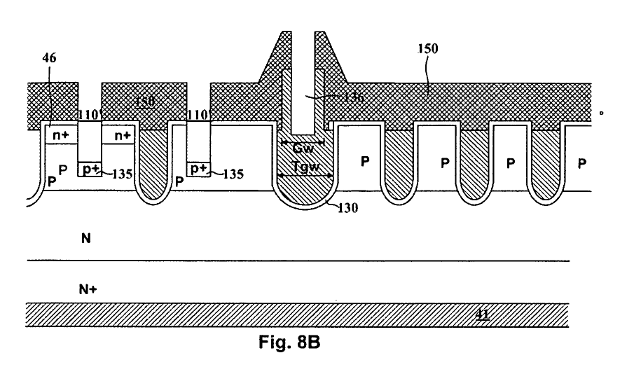

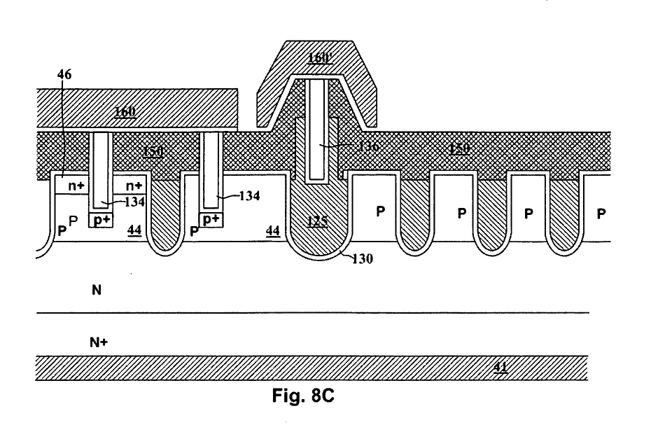

Refer to FIGS. 7A to 7E shown a series of exemplary steps that are performed to form the MOS element of the said embodiment according to the FIG. 5.

For a preferred embodiment shown in FIG. 7A, the first semiconductor type epitaxial layer 42 is formed on the substrate 40, and the second semiconductor type epitaxial layer 440 formed on the first semiconductor type epitaxial layer 42. The substrate 40 and the first semiconductor type epitaxial layer 42 are N-type semiconductor while the substrate 40 has higher N-type doping concentration than the first semiconductor type epitaxial layer 42, and the second semiconductor type epitaxial layer 440 is P-type semiconductor.

In FIG. 7B, a trench mask is formed by covering the surface of the second semiconductor type epitaxial layer 440 with an oxide layer, which is then conventionally exposed and patterned to leave mask portions, and the patterned mask defines a plurality of narrow trenches 124, at least a wide trench 121, and a plurality of floating trenches 122. A dry silicon etching is performed through the mask opening to a certain depth, and the trenches 120, 121, and 122 are formed. The second semiconductor type epitaxial layer 440 is divided into the body regions 44 by the trenches 120, 121, and 122. After the processes above, the mask portion is removed, and a step of arsenic ion implantation is performed to form a plurality of underneath doped areas 100 around each bottom of trenches 120, 121, and 122 for further reducing Rds. An oxide layer is performed to cover on the each inner surface of trenches 120, 121, and 122, and the top surface of the second semiconductor type epitaxial layer 440, so the gate oxide layer 130 is formed. The each underneath doped area 100 has higher doping concentration than the first semiconductor type epitaxial layer 42.

In FIG. 7C, the each one of the trenches 120, 121, and 122 is filled with doped poly, combination of doped poly, or non-doped poly, and the filling-in material, doped poly, combination of doped poly, or non-doped poly, is etched back to expose the potion of the gate oxide layer 130 that extends over the top surface of the body region 44. For further reducing gate resistance, a layer of silicide is formed on top of poly or inside of the doped poly (not shown) as alternative. The second mask is then applied to form the source regions 46, followed by an N dopant ion implantation and diffusion step for source region drive-in.

In FIG. 7D, the process continues with the deposition of oxide layer 150 over entire structure of the MOS element. A contact mask is applied to carry out a contact etch to open a plurality of contact openings 110 by applying a dry oxide etch through the oxide layer 150 and followed by a dry silicon etch to open the contact openings 110 by etching through the source regions 46 and extending into the body regions 44. A BF2 ion implantation process is followed to form the contact implantation part 135 for reducing the contact resistance between the body regions 44. The contact implantation part 135 is carried out by a second semiconductor type doping with higher doping concentration than the body region 44.

In FIG. 7E, the contact openings 110 shown in FIG. 7D is filled with metal, such as Ti/TiN, Co/TiN or Mo/TiN, to form the source contact plug 134 and the gate contact plug 136. Then, a tungsten etch back and Ti/TiN, Co/TiN or Mo/TiN etch back is performed followed by a metal layer formation. A metal mask is applied to pattern the metal layer into the source metal 160 and the gate metal layer 160′. The each source contact plug 134 is formed to contact the corresponding source regions 46, the body region 44, and the source metal 160 so that the source metal 160 is electrically connected with the corresponding source region 46 and the body region 44 by the source contact plug 134. The gate contact plug 136 is formed to contact the wide trench gate 125 and the gate metal 160′ so that the gate metal 160′ is electrically connected with the corresponding the wide trench gate 125 by the gate contact plug 136.

The number of masks used in the two preferred embodiment mentioned above is different. In the first processing, four masks is needed during entire process, while in the second processing, an additional terrace poly mask is applied to implement the function of avoiding shortage problem, that is to say, five masks is needed in the second preferred embodiment.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET comprising:
a substrate made of first type semiconductor;
an epitaxial layer made of the first type semiconductor over substrate and having a lower doping concentration than the substrate;
a plurality of body regions made of second type semiconductor over the first epitaxial layer as body regions of the trench MOSFET;
a plurality of source regions made of first type semiconductor over the body regions as source regions of the trench MOSFET and having a higher doping concentration than the epitaxial layer;
a plurality of narrow trench gates formed to reach the epitaxial layer through the source region and the body region;
at least a wide trench gate formed to reach the epitaxial layer through the body region;
a gate insulation layer formed to wrap the each narrow trench gate and the wide trench gate;
an insulating layer covered on the source regions;
a source metal covered on the insulating layer;
a gate metal covered on the insulating layer isolated to the source;
a plurality of source contact plugs each of which is extended from the source metal and through the insulating layer to contact the corresponding source regions and the corresponding body region; and
at least a gate contact plug which is extended from the gate metal and through the insulating layer to contact the corresponding wide trench gate;
wherein the first type semiconductor which is one type of N-type semiconductor and P-type semiconductor, and the second type semiconductor is the other; the source metal is electrically connected to the source regions and the body regions by the source contact plugs; the gate metal is electrically connected to the wide trench gate by the gate contact plug; and the wide trench gate is extended into the insulating layer covered on the top thereof so the polysilicon in the wide trench.

2. The MOSFET of claim 1, wherein an underneath doped area which is heavily doped with the first type semiconductor underneath each bottom of the narrow trenched gates and the wide trench gate.

3. The MOSFET of claim 1, wherein further comprises a contact implantation part at the bottom of each source contact plug, and the contact implantation part is carried out by the second semiconductor type doping with higher doping concentration than the body region.

4. The MOSFET of claim 1, wherein further comprises a backside metal disposed on backside of said substrate as drain regions.

5. The MOSFET of claim 1, wherein further comprises a plurality of floating trench rings serving as termination.

6. The MOSFET of claim 1, wherein the polysilicon in the gate of the narrow trench gates and the wide trench gate is chosen from doped polysilicon.

7. The MOSFET of claims 1, wherein the polysilicon in the gate of the narrow trench gates and the wide trench gate is chosen from a combination of doped polysilicon and non-doped polysilicon.
